(19) United States
(12) Patent Application Publication
(10) Pub. No.: US 2009/0206430 A1
(43) Pub. Date: Aug. 20, 2009

(54) SOLID-STATE IMAGING DEVICE AND METHOD FOR MANUFACTURING THE SAME

(76) Inventors: Toshihiro Higuchi, Osaka (JP); Masayuki Aoyama, Osaka (JP); Tomoko Komatsu, Kyoto (JP)

Correspondence Address: MCDERMOTT WILL & EMERY LLP, 600 13TH STREET, NW, WASHINGTON, DC, 20005-3096, US

(21) Appl. No.: 11/997,959

(22) PCT Filed: Apr. 25, 2006
(86) PCT No.: PCT/JP2006/308623

§ 371 Date: Feb. 5, 2008

(30) Foreign Application Priority Data
Aug. 19, 2005 (JP) 2005-239100

(51) Int. Cl. H01L 31/0232; H01L 21/302

(52) U.S. Cl. 257/432; 438/69; 257/E31.127; 257/E21.214

(57) ABSTRACT

A pattern (6B) is formed by performing selective exposure and development on a photosensitive resist (6A), and then the pattern (6B) is decolorized by irradiating the pattern with ultraviolet or visible light. Then, a microlens (6) is formed by deforming the shape of the pattern (6B) into a microlens shape by heating. An inequality of h/a≧1 is satisfied, where, (h) is the height of the microlens (6), and (2a) is the length of the bottom plane of the microlens (6) in a short side direction when viewed from the upper plane.

### TECHNICAL FIELD

The present invention relates to solid-state imaging devices in which solid-state image sensing elements, in particular, solid-state color image sensing elements or the like are provided thereabove with respective microlenses with high light collection efficiencies, and to methods for manufacturing the same.

### BACKGROUND ART

In recent years, solid-state imaging devices have been utilized as light receiving elements in a videotape camera-recorder or a digital still camera because solid-state image sensing elements incorporated therein have excellent characteristics such as compact size, light weight, long life, small afterimage, and low power consumption. One of fabrication steps of such a solid-state imaging device is a microlens formation step, by which a microlens with a desired curvature is formed to enable improvement of sensitivity of the solid-state imaging device.

The technique disclosed in Patent Document 1 describes the approach that a photosensitive resin with a thermosetting property is decolorized by irradiation with ultraviolet light or visible light and then the resulting photosensitive resin is heated to accurately form a microlens with a desired shape.

The technique disclosed in Patent Document 2 describes the approach that by using a photomask formed with a light shielding pattern having a stepwise-varying light transmission amount in order to secure a desired light intensity distribution on the surface to be exposed, a microlens shape is formed at the time of patterning of a photosensitive resist, and then the formed shape is transferred by dry etching to an underlying layer to accurately form a microlens with a desired shape.

Patent Document 1: Japanese Patent No. 2945440

Patent Document 2: Japanese Patent No. 3158296

### DISCLOSURE OF INVENTION

### Problems to be Solved by the Invention

With recent miniaturization of solid-state imaging devices, a solid-state imaging device capable of offering higher sensitivity, being fabricated at a low cost, and ensuring a stable supply has become indispensable.

In the technique disclosed in Patent Document 1, however, the microlens is formed by utilizing only the difference in the physical properties between thermosoftening and thermosetting obtained in mixing materials for the lens. Therefore, with this technique, only a microlens with an aspect ratio (the value of h/a, where h is the height of the microlens and 2a is the length of the bottom plane of the microlens in a short side direction when viewed from the upper plane) below 1 can be formed. This makes it difficult to provide a high-sensitive solid-state imaging device incorporating microlenses capable of providing high light collection efficiency.

Moreover, in the technique disclosed in Patent Document 2, the microlens formed after the patterning (the photoresist pattern having the microlens shape formed by exposure and development) cannot secure solvent resistance. Since this shape is then transferred by dry etching to the underlying layer, the transfer process requires an expensive system and a long process time. This makes it difficult to provide a solid-state imaging device at a low cost.

The present invention has been made in consideration of such problems, and its object is to provide a high-sensitive solid-state imaging device with stability and at a low cost.

### Means for Solving the Problems

To solve the above problems, a first solid-state imaging device according to the present invention is a solid-state imaging device provided with a heat-flow type microlens made in the manner in which a pattern formed by subjecting a photosensitive resist to selective exposure and development is decolorized by irradiation with ultraviolet light or visible light and then the resulting pattern is heated to deform the shape thereof into a microlens shape, and an inequality of h/a≧1 is satisfied where h is the height of the microlens and 2a is the length of the bottom plane of the microlens in a short side direction when viewed from the upper plane.

Preferably, in the first solid-state imaging device according to the present invention, the material for the microlens absorbs light with any wavelength not less than 250 nm and less than 360 nm.

A first method for manufacturing a solid-state imaging device according to the present invention is a method for manufacturing a solid-state imaging device provided with a heat-flow type microlens, and the method includes: the step (a) of subjecting a photosensitive resist to selective exposure and development to form a pattern; the step (b) of decolorizing the pattern by irradiation with ultraviolet light or visible light; and the step (c) of heating, after the step (b), the pattern to deform the shape thereof into a microlens shape, thereby forming a microlens. In this method, an inequality of h/a≧1 is satisfied where h is the height of the microlens and 2a is the length of the bottom plane of the microlens in a short side direction when viewed from the upper plane, and the method further includes, after the step (a), the step of irradiating the pattern with at least i-line.

Preferably, in the first method for manufacturing a solid-state imaging device according to the present invention, in the step (b), the pattern is irradiated with i-line.

A second solid-state imaging device according to the present invention is a solid-state imaging device provided with a microlens made by utilizing at least the manner in which a photosensitive resist is subjected to exposure while the light irradiation amount is controlled by a photomask formed with a light shielding pattern having a stepwise-varying light transmission amount in order to secure a desired light intensity distribution on the surface of the photosensitive resist and then the photosensitive resist is subjected to development patterning to leave a gradient amount of the photosensitive resist, and the material for the microlens has an absorbance greater than 0.3 um⁻¹ to light with any wavelength not less than 250 nm and less than 360 mm.

A second method for manufacturing a solid-state imaging device according to the present invention is a method for manufacturing a solid-state imaging device provided with a microlens, and the method includes: the step (a) of subjecting a photosensitive resist to exposure while the light irradiation amount is controlled by a photomask formed with a light shielding pattern having a stepwise-varying light transmission amount in order to secure a desired light intensity distribution on the surface of the photosensitive resist; and the step (b) of subjecting, after the step (a), the photosensitive resist to development patterning to leave a gradient amount of the photosensitive resist, thereby forming the microlens. In this method, the material for the microlens has an absorbance greater than 0.3 um⁻¹ to light with any wavelength not less than 250 nm and less than 360 nm, and the method further includes, after the step (b), the step (c) of irradiating the photosensitive resist with at least j-line.

Preferably, in the second method for manufacturing a solid-state imaging device according to the present invention, in the step (c), the photosensitive resist is decolorized.

### TECHNICAL ADVANTAGES

With the present invention, a high-sensitive solid-state imaging device can be provided with stability and at a low cost.

### BRIEF DESCRIPTION OF THE DRAWINGS

FIGS. 1(a) and 1(b) are a sectional view and a plan view of a solid-state imaging device according to a first embodiment of the present invention, respectively.

FIGS. 2(a) to 2(g) are sectional views showing a method for manufacturing a solid-state imaging device according to a second embodiment of the present invention in the order of its process steps.

FIG. 3 is a sectional view of a solid-state imaging device according to a third embodiment of the present invention.

FIGS. 4(a) to 4(d) are sectional views showing a method for manufacturing a solid-state imaging device according to a fourth embodiment of the present invention in the order of its process steps.

### EXPLANATION OF REFERENCES

1 Substrate for a solid-state image sensing element
2 Photodiode
3 First acrylic flattening film
4 Color filter
5 Second acrylic flattening film
6 Microlens
6A Resist
6B Pattern
11 Substrate for a solid-state image sensing element
12 Photodiode
13 First acrylic flattening film
14 Color filter
15 Second acrylic flattening film
16 Microlens
16A Resist
17 Photomask

### BEST MODE FOR CARRYING OUT THE INVENTION

### First Embodiment

A solid-state imaging device according to a first embodiment of the present invention will be described below with reference to the accompanying drawings.

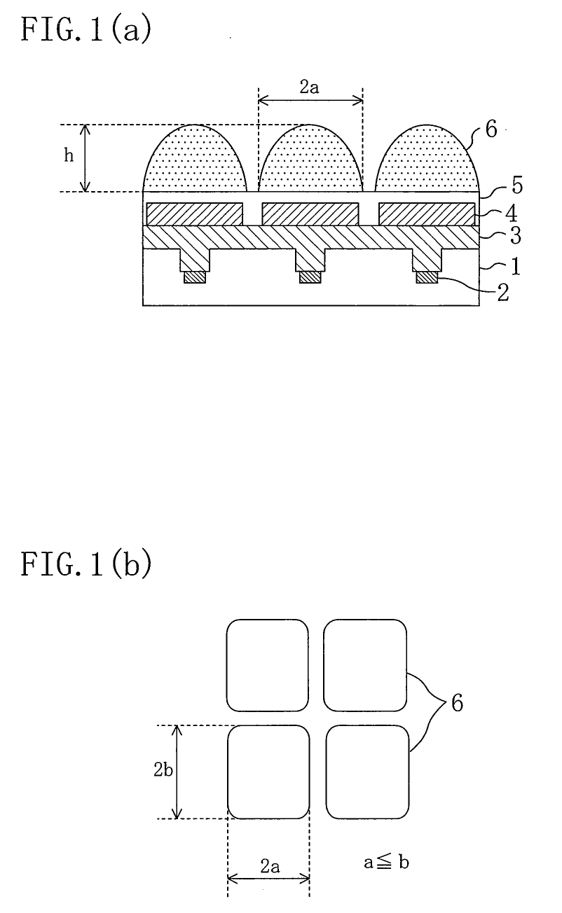

FIGS. 1(a) and 1(b) are a sectional view and a plan view of the solid-state imaging device according to the first embodiment, respectively.

Referring to FIG. 1(a), recesses associated with respective pixels are provided in the surface of a substrate 1 for a CCD (Charge Coupled Device)-type solid-state image sensing element. Photodiodes 2 for converting an incoming light into an electrical signal are provided in the bottom portions of the recesses, respectively. On the substrate 1 for the solid-state image sensing element, a first acrylic flattening film 3 is formed which flattens unevenness of the substrate surface. On the first acrylic flattening film 3, color filters 4 are formed to be associated with the photodiodes 2, respectively. On the color filters 4, a second acrylic flattening film 5 is formed which flattens unevenness generated due to the color filters 4. On the second acrylic flattening film 5, microlenses 6 are formed to be associated with the photodiodes 2, respectively.

In the first embodiment, as the material for the microlens 6, use is made of, for example, a positive type photosensitive resist which contains naphthoquinone diazide as a sensitizer and which can absorb light with any wavelength not less than 250 nm and less than 360 nm. Exposure with ultraviolet light or visible light improves the transmissivity of the visible light range in naphthoquinone diazide to 80% or higher. In addition, by subjecting this resist to thermal treatment at 120 to 280° C., the shape of the resist is becoming altered due to its thermoplasticity and simultaneously becoming fixed due to its thermosetting property. Finally, the difference between the extents of their changes determines the shape of the microlens 6 made of this resist.

The first embodiment is characterized in that as shown in FIGS. 1(a) and 1(b), the aspect ratio satisfies the relation h/a≧1 where h is the height of the microlens 6 and 2a is the length of the bottom plane of the microlens 6 in a short side direction when viewed from the upper plane. Note that the length of the bottom plane of the microlens 6 in a long side direction is represented as 2b (b≧a). The bottom shape of the microlens 6 is not limited to a specific shape. For example, in the case where the bottom shape is an ellipse or the like, the length of the shortest diameter passing through the barycenter of the shape is represented as the length 2a in a short side direction, and the length of the longest diameter passing therethrough is represented as the length 2b in a long side direction.

In the solid-state imaging device of the first embodiment constructed as shown above, the aspect ratio h/a of the microlens 6 is 1 or higher. Thereby, it is confirmed that the light collection ability of the device is further improved as compared with the conventional microlens, and thus the sensitivity thereof is improved by about 1 to 15%.

For the conventional microlens, the presence of an organic layer such as an adhesive or the like on the microlens reduces the light collection efficiency. As a result, the sensitivity of the solid-state imaging device decreases to about a half of the sensitivity in the case of the absence of the organic layer. However, for the solid-state imaging device of the first embodiment, the microlens 6 with an aspect ratio h/a of 1 or higher is formed. Therefore, even for the presence of an organic layer on the microlens 6, the sensitivity equal to or more than the sensitivity of the conventional solid-state imaging device without the organic layer such as an adhesive or the like can be provided.

### Second Embodiment

A method for manufacturing a solid-state imaging device according to a second embodiment of the present invention will be described below with reference to the accompanying drawings.

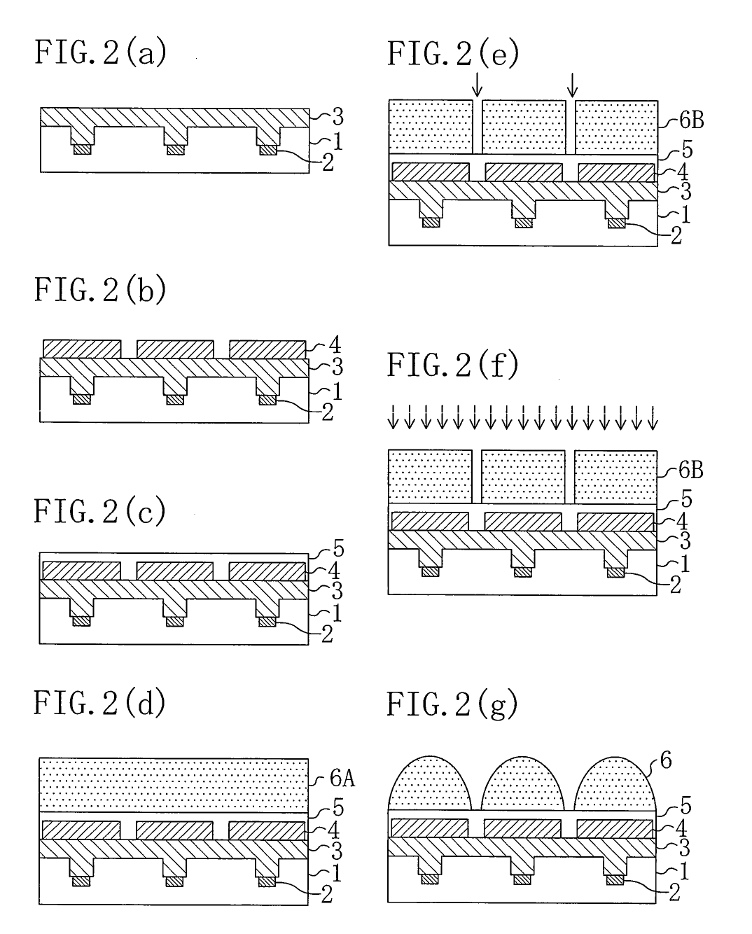

FIGS. 2(a) to 2(g) are sectional views showing the method for manufacturing a solid-state imaging device according to the second embodiment, to be more specific, a formation method of the microlens of the solid-state imaging device according to the first embodiment in the order of its formation process steps.

Referring to FIG. 2(a), first, onto the whole of an uneven surface of the substrate 1 for the solid-state image sensing element in which the photodiode 2 for converting an incoming light into an electrical signal is provided on each pixel, for example, acrylic resin is applied by spin coating, and then the applied resin is heated and dried, for example, at about 180 to 250° C. for about 60 to 600 seconds, thereby forming the first acrylic flattening film 3.

Next, as shown in FIG. 2(b), on the first acrylic flattening film 3, the color filters 4 are formed to be associated with the photodiodes 2, respectively.

Subsequently, as shown in FIG. 2(c), onto the entire surfaces of the color filters 4, for example, acrylic resin is applied by spin coating to fill unevenness generated due to the color filters 4, and then the applied resin is heated and dried, for example, at about 180 to 250° C. for about 60 to 600 seconds. In the second embodiment, such application and dry steps are repeatedly conducted, for example, twice to eight times to form the second acrylic flattening film 5 with a high flatness.

As shown in FIG. 2(d), onto the entire surface of the second acrylic flattening film 5, for example, a positive type photosensitive resist 6A as the material for the microlens is applied by spin coating to have a thickness of, for example, 0.5 μm or greater, and then the applied resist 6A is dried, for example, at a low temperature of about 90 to 120° C. for about 10 to 600 seconds.

In the second embodiment, as the resist 6A as the microlens material, use is made of, for example, a positive type photosensitive resist which contains naphthoquinone diazide as a sensitizer and which can absorb light with any wavelength not less than 250 nm and less than 360 nm. Exposure with ultraviolet light or visible light improves the transmissivity of the visible light range in naphthoquinone diazide to 80% or higher. In addition, by subjecting the resist 6A to thermal treatment at 120 to 280° C., the shape of the resist is becoming altered due to its thermoplasticity and simultaneously becoming fixed due to its thermosetting property. Finally, the difference between the extents of their changes determines the shape of the microlens 6 (see FIG. 2(g)) made of the resist 6A.

Next, as shown in FIG. 2(e), the resist 6A is subjected to, for example, selective exposure with i-line at an exposure energy of 100 to 1000 mJ. After this exposure, the resulting resist 6A is developed using, for example, a TMAH (Tetramethyl Ammonium Hydroxide) solution to form a desired pattern 6B made of remaining portions of the resist 6A.

Subsequently, as shown in FIG. 2(f), the pattern 6B and the second acrylic flattening film 5 are subjected to overall exposure with at least i-line at an exposure energy of 100 mJ or greater. Thereby, cross-linking reaction of some portions of the pattern 6B is advanced and simultaneously the visible-light transmissivity of the pattern 6B is improved to 80% or higher.

As shown in FIG. 2(g), the pattern 6B is heated, for example, at an intermediate temperature of about 120 to 180° C. for about 60 to 600 seconds. Thereby, both of the thermoplastic and thermosetting performances of the pattern 6B can be controlled, whereby the microlenses 6 are formed which have surfaces of a desired curvature and a predetermined refractive index. That is to say, the pattern 6B can be deformed into a desired microlens shape. Then, the microlenses 6 are subjected to thermal treatment, for example, at a high temperature of about 190 to 280° C. for about 60 to 600 seconds to improve the reliability of the microlens 6, to be more specific, the thermal resistance, the solvent resistance (the property resistant to alteration by solvent), and the like of the microlens 6.

As described above, with the second embodiment, the pattern 6B made of the microlens material capable of absorbing light with any wavelength not less than 250 nm and less than 360 nm is irradiated with i-line in the step shown in FIG. 2(f). This irradiation excites resin in the pattern 6B to advance cross-linking thereof, so that a small degree of resin flow (the difference in the physical properties between thermosoftening and thermosetting) can be attained which cannot be attained by the conventional material mixing performed in the early stage of the formation method or the temperature control in the step shown in FIG. 2(g). As a result, the microlens 6 with an aspect ratio of 1 or higher can be formed which is difficult to form by the conventional technique. This improves the light collection ability of the microlens 6, so that a high-sensitive solid-state imaging device can be manufactured.

In the second embodiment, it is confirmed that even though irradiation with a great amount of i-line is performed in the step shown in FIG. 2(f), thermosetting is not advanced to such an extent that the pattern would completely remain in the pattern shape having been formed in the step shown in FIG. 2(e).

In the second embodiment, in the step shown in FIG. 2(f), i-line is used as light for irradiating the pattern 6B, but the light for use in irradiation is not limited to this. For example, if as the microlens material to be formed with the pattern 6B, use is made of a material whose absorbance of light with a wavelength not less than 250 nm and less than 360 nm is 0.3 um⁻¹ or smaller, radiation with j-line as a substitute for the i-line can also provide the same effects as those of the second embodiment. In practice, the sensitizer contained in the microlens material should be efficiently altered with light to become transparent. Therefore, it is desirable to simultaneously irradiate the pattern 6B with light with a wavelength effective for decolorization and i-line and/or j-line.

In the second embodiment, i-line irradiation is performed in the decolorization step (the step shown in FIG. 2(f)). Alternatively, this irradiation may be performed in another step.

In the second embodiment, visible light may be used in the decolorization step.

### Third Embodiment

A solid-state imaging device according to a third embodiment of the present invention will be described below with reference to the accompanying drawings.

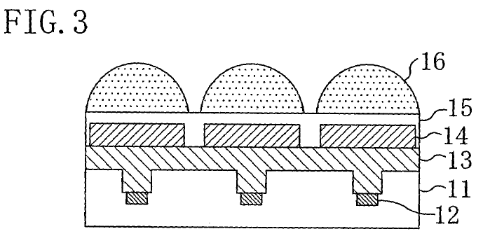

FIG. 3 is a sectional view of the solid-state imaging device according to the third embodiment.

Referring to FIG. 3, recesses associated with respective pixels are provided in the surface of a substrate 11 for a CCD-type solid-state image sensing element. Photodiodes 12 for converting an incoming light into an electrical signal are provided in the bottom portions of the recesses, respectively. On the substrate 11 for the solid-state image sensing element, a first acrylic flattening film 13 is formed which flattens unevenness of the substrate surface. On the first acrylic flattening film 13, color filters 14 are formed to be associated with the photodiodes 12, respectively. On the color filters 14, a second acrylic flattening film 15 is formed which flattens unevenness generated due to the color filters 14. On the second acrylic flattening film 15, microlenses 16 are formed to be associated with the photodiodes 12, respectively. The microlenses 16 are formed in the following manner. First, exposure is performed on a photosensitive resist while the light irradiation amount is controlled by a photomask formed with a light shielding pattern having a stepwise-varying light transmission amount in order to secure a desired light intensity distribution on the surface to be exposed. Then, the photosensitive resist is subjected to development patterning to leave a gradient amount of the photosensitive resist.

In the third embodiment, as the material for the microlens 16, use is made of, for example, a positive type photosensitive resist which contains naphthoquinone diazide as a sensitizer and which has an absorbance greater than 0.3 um⁻¹ to light with any wavelength not less than 250 nm and less than 360 nm. Since this material has an absorbance greater than 0.3 um⁻¹ to light with any wavelength not less than 250 nm and less than 360 nm, a 25 microlens pattern after development is irradiated with at least j-line to completely fix the microlens shape after development and concurrently the transmissivity of the visible light range in naphthoquinone diazide is improved to 80% or higher.

Note that the absorbance is defined as follows.

A=log(1/T) (Equation 1)

In Equation 1, A is the absorbance and T is the transmissivity. The absorbance is measured using a decolorized, hardened film fixed on a glass.

In the solid-state imaging device of the third embodiment constructed as described above, the microlens 16 is formed in the manner in which exposure is performed on a photosensitive resist while the light irradiation amount is controlled by a photomask formed with a light shielding pattern having a stepwise-varying light transmission amount in order to secure a desired light intensity distribution on the surface to be exposed, and then the photosensitive resist is subjected to development patterning to leave a gradient amount of the photosensitive resist. Thereafter, the formed microlens is irradiated with j-line to completely fix the microlens shape, whereby a dry etching apparatus conventionally necessary for formation thereof becomes unnecessary. This provides a reduced cost and improved throughput. Therefore, a solid-state imaging device can be provided with stability and at a low cost.

In the solid-state imaging device of the third embodiment shown in FIG. 3, the microlenses having the same shape are formed as the microlenses 16. However, the present invention is not limited to this. To be more specific, the present invention can also be applied to the case where, for example, the microlens shapes after development patterning are changed according to the positions of the pixels of the solid-state imaging device.

### Fourth Embodiment

A method for manufacturing a solid-state imaging device according to a fourth embodiment of the present invention will be described below with reference to the accompanying drawings.

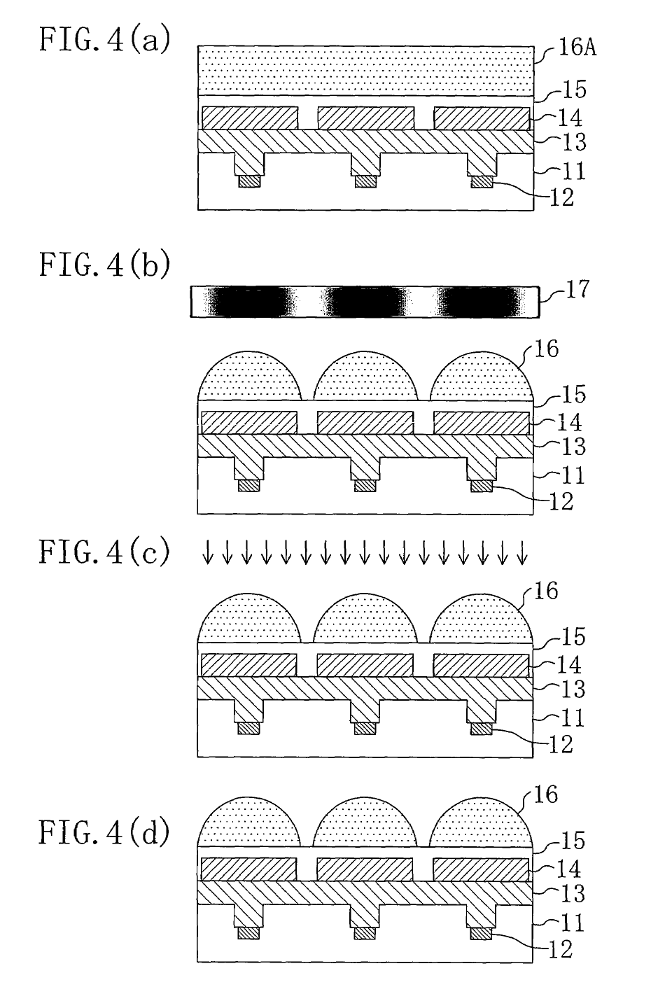

FIGS. 4(a) to 4(d) are sectional views showing the method for manufacturing a solid-state imaging device according to the fourth embodiment, to be more specific, a formation method of the microlens of the solid-state imaging device according to the third embodiment in the order of its formation process steps.

Referring to FIG. 4(a), first, onto the whole of an uneven surface of the substrate 11 for the solid-state image sensing element in which the photodiode 12 for converting an incoming light into an electrical signal is provided on each pixel, for example, acrylic resin is applied by spin coating, and then the applied resin is heated and dried, for example, at about 180 to 250° C. for about 60 to 600 seconds, thereby forming the first acrylic flattening film 13. Next, on the first acrylic flattening film 13, the color filters 14 are formed to be associated with the photodiodes 12, respectively. Then, onto the entire surfaces of the color filters 14, for example, acrylic resin is applied by spin coating to fill unevenness generated due to the color filters 14, and then the applied resin is heated and dried, for example, at about 180 to 250° C. for about 60 to 600 seconds. In the fourth embodiment, such application and dry steps are repeatedly conducted, for example, twice to eight times to form the second acrylic flattening film 15 with a high flatness. Onto the entire surface of the second acrylic flattening film 15, for example, a positive type photosensitive resist 16A as the material for the microlens is applied by spin coating to have a thickness of, for example, 0.5 μm or greater, and then the applied resist 16A is dried, for example, at a low temperature of about 90 to 120° C. for about 10 to 600 seconds.

In the fourth embodiment, as the resist 16A as the microlens material, use is made of, for example, a positive type photosensitive resist which contains naphthoquinone diazide as a sensitizer and which has an absorbance greater than 0.3 um⁻¹ to light with any wavelength not less than 250 nm and less than 360 nm. Exposure with ultraviolet light or visible light improves the transmissivity of the visible light range in naphthoquinone diazide to 80% or higher.

Next, as shown in FIG. 4(b), the resist 16A is subjected to, for example, selective exposure with i-line at an exposure energy of 100 to 1000 mJ while the light irradiation amount is controlled by a photomask 17 formed with a light shielding pattern having a stepwise-varying light transmission amount in order to secure a desired light intensity distribution on the surface of the resist 16A. After this exposure, the resulting resist 16A is developed using, for example, a TMAH solution to leave a gradient amount of the photosensitive resist. Thereby, the microlens 16 with a desired shape is formed.

Subsequently, as shown in FIG. 4(c), the microlens 16 and the second acrylic flattening film 15 are subjected to overall exposure with at least j-line at an exposure energy of 100 mJ or greater (in terms of j-line). Thereby, the microlens shape is completely fixed and concurrently the visible-light transmissivity of the microlens 16 is improved to 80% or higher. That is to say, the microlens 16 is decolorized.

As shown in FIG. 4(d), the microlens 16 is heated, for example, at a temperature of about 120 to 280° C. for about 60 to 600 seconds to further improve the reliability of the microlens 16, to be more specific, the thermal resistance, the solvent resistance (the property resistant to alteration by solvent), and the like of the microlens 16. Since the shape of the microlens 16 has already been fixed completely by irradiating the microlens 16 with a sufficient amount of j-line in the step shown in FIG. 4(c), only the reliability can be improved with the shape after development kept.

As described above, with the fourth embodiment, the microlens 16 made of the material having an absorbance greater than 0.3 um⁻¹ to light with any wavelength not less than 250 nm and less than 360 nm is irradiated with at least j-line in the step shown in FIG. 4(c). This irradiation excites resin in the microlens 16 to rapidly advance cross-linking thereof, so that resin flow caused by thermosoftening hardly or never occurs. As a result, the shape of the microlens 16 after development patterning can be maintained. That is to say, in the formation method of the microlens 16 carried out in the manner in which exposure is performed on the resist 16A while the light irradiation amount is controlled by the photomask 17 formed with a light shielding pattern having a stepwise-varying light transmission amount in order to secure a desired light intensity distribution on the surface to be exposed and then the resist 16A is subjected to development patterning to leave a gradient amount of the resist 16A, the microlens 16 can be formed without employing a dry etching apparatus. Therefore, the solid-state imaging device including the microlens 16 with a desired shape can be provided with stability and at a very low cost.

In the method for manufacturing a solid-state imaging device according to the fourth embodiment shown in FIGS. 4(a) to 4(d), the microlenses having the same shape are formed as the microlenses 16. However, the present invention is not limited to this. To be more specific, the present invention can also be applied to the case where, for example, the microlens shapes after development patterning are changed according to the positions of the pixels of the solid-state imaging device.

As can be seen from the above, the present invention has been described based on the first to fourth embodiments. However, an exemplary application of the present invention is not limited to these embodiments.

In the first to fourth embodiments, acrylic resin is used for the flattening film. However, the material for the flattening film is not limited to acrylic resin, and another heat-resistant resin with a high transparency to visible light can also be used as the flattening film.

In the first to fourth embodiments, for example, a photosensitive resist containing pigments or dyes may be used as the material for the color filter. Alternatively, the color filter may be formed by etching a non-photosensitive resist containing pigments or dyes. The colors of the pigments or the dyes to be used may be complementary colors or primary colors.

The present invention may be employed for a method for forming a microlens by a transfer process using dry etching. To be more specific, a microlens with a desired shape may be formed in the manner in which a microlens before transfer (a photoresist pattern with a microlens shape) is formed by employing any of the embodiments of the present invention and the formed shape is transferred to an underlying layer by dry etching.

### INDUSTRIAL APPLICABILITY

The present invention relates to solid-state imaging devices with microlenses and their manufacturing methods. If it is employed for a solid-state imaging device and the like incorporated in a digital video camera, a digital still camera, a camera-equipped cellular phone, or the like, a high-sensitive solid-state imaging device can be provided with stability and at a low cost, which is very useful in industry.

What is claimed is:

1. A solid-state imaging device provided with a heat-flow type microlens made in the manner in which a pattern formed by subjecting a photosensitive resist to selective exposure and development is decolorized by irradiation with ultraviolet light or visible light and then the resulting pattern is heated to deform the shape thereof into a microlens shape,
wherein an inequality of h/a≧1 is satisfied where h is the height of the microlens and 2a is the length of the bottom plane of the microlens in a short side direction when viewed from the upper plane.

2. The device of claim 1, wherein the material for the microlens absorbs light with any wavelength not less than 250 nm and less than 360 nm.

3. A method for manufacturing a solid-state imaging device provided with a heat-flow type microlens, the method comprising:
the step (a) of subjecting a photosensitive resist to selective exposure and development to form a pattern;
the step (b) of decolorizing the pattern by irradiation with ultraviolet light or visible light; and
the step (c) of heating, after the step (b), the pattern to deform the shape thereof into a microlens shape, thereby forming a microlens,
wherein an inequality of h/a≧1 is satisfied where h is the height of the microlens and 2a is the length of the bottom plane of the microlens in a short side direction when viewed from the upper plane, and
the method further comprises, after the step (a), the step of irradiating the pattern with at least i-line.

4. The method of claim 3,
wherein in the step (b), the pattern is irradiated with i-line.

5. A solid-state imaging device provided with a microlens made by utilizing at least the manner in which a photosensitive resist is subjected to exposure while the light irradiation amount is controlled by a photomask formed with a light shielding pattern having a stepwise-varying light transmission amount in order to secure a desired light intensity distribution on the surface of the photosensitive resist and then the photosensitive resist is subjected to development patterning to leave a gradient amount of the photosensitive resist,
wherein the material for the microlens has an absorbance greater than 0.3 um⁻¹ to light with any wavelength not less than 250 nm and less than 360 nm.

6. A method for manufacturing a solid-state imaging device provided with a microlens, the method comprising:
the step (a) of subjecting a photosensitive resist to exposure while the light irradiation amount is controlled by a photomask formed with a light shielding pattern having a stepwise-varying light transmission amount in order to secure a desired light intensity distribution on the surface of the photosensitive resist; and
the step (b) of subjecting, after the step (a), the photosensitive resist to development patterning to leave a gradient amount of the photosensitive resist, thereby forming the microlens,
wherein the material for the microlens has an absorbance greater than 0.3 um⁻¹ to light with any wavelength not less than 250 nm and less than 360 nm, and
the method further comprises, after the step (b), the step (c) of irradiating the photosensitive resist with at least j-line.

7. The method of claim 6,
wherein in the step (c), the photosensitive resist is decolorized.
